(19) United States
(12) Patent Application Publication
(10) Pub. No.: US 2026/0164867 A1
(43) Pub. Date: Jun. 11, 2026

(54) SELF-FORMING SUB-MOUNT / LEAD FRAME

(71) Applicant: CreeLED, Inc., Durham, NC (US)

(72) Inventors: Michael Check, Holly Springs, NC (US); David Suich, Durham, NC (US); Joseph G. Sokol, Durham, NC (US); Colin Blakely, Raleigh, NC (US)

(21) Appl. No.: 18/975,538

(22) Filed: Dec. 10, 2024

(51) Int. Cl. H10H 20/857; H10H 20/01; H10H 20/85

(52) U.S. Cl. CPC H10H 20/857; H10H 20/0364; H10H 20/8506

(57) ABSTRACT

Light-emitting diode (LED) devices and, more particularly, self-folding lead frames in LED packages are disclosed. Exemplary lead frame structures are provided that include relief lines formed in the lead frame structure that, in response to a force being applied to the lead frame structure, for example, when an LED chip is placed on the lead frame structure, cause the lead frame to self-fold into a predefined shape. The self-folding lead frame can provide the LED package with better manipulation of light control from the package itself than conventional lead frames, while simplifying the manufacturing process.

### FIELD OF THE DISCLOSURE

The present disclosure relates to light-emitting diode (LED) devices, and more particularly to self-folding lead frames in LED packages.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs continue to enable a variety of new LED display and general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that provide mechanical support, electrical connections, and encapsulation for LED emitters. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices and more particularly to self-folding lead frames in LED packages. Exemplary lead frame structures are provided that include relief lines formed in the lead frame structure that, in response to a force being applied to the lead frame structure, for example, when an LED chip is placed on the lead frame structure, cause the lead frame to self-fold into a predefined shape. The self-folding lead frame can provide the LED package with better manipulation of light control from the package itself than conventional lead frames, while simplifying the manufacturing process.

In one aspect, an LED package includes a housing, a lead frame structure within the housing, the lead frame structure comprising relief lines that are formed therein, that in response to a force being applied to the lead frame structure, cause the lead frame structure to fold along the relief lines, and an LED chip positioned on the lead frame structure. In an embodiment, the lead frame structure is folded such that a portion of the lead frame structure is at least flush with a light emitting portion of the LED chip. In an embodiment, the lead frame structure is folded such that a portion of the lead frame structure folds down to form an electrical connection with one or more electrodes. In an embodiment, the lead frame structure comprises two layers with different coefficients of thermal expansion. In an embodiment, the lead frame structure folds in response to a change in temperature. In an embodiment, the relief lines are formed via etching from one or more of laser etching, chemical etching, or mechanical etching. In an embodiment, the lead frame structure folds via plastic deformation. In an embodiment, the lead frame structure folds via elastic deformation. In an embodiment, the lead frame structure is folded in response to force from a die attach arm placing the LED chip on the lead frame structure. In an embodiment, the relief lines are patterned based on a predefined fold pattern.

In another aspect, a method for fabricating an LED package includes forming one or more relief lines onto a lead frame structure within a housing. The method also includes mounting an LED chip onto the lead frame structure and causing the lead frame structure to fold along the one or more relief lines, resulting in a lead frame structure with predefined fold pattern. In an embodiment, the causing the lead frame structure to fold comprises applying force with a die attach arm that mounts the LED chip onto the lead frame structure. In an embodiment, the causing the lead frame structure to fold comprises applying thermal energy to the lead frame structure. In an embodiment, the method also includes causing the lead frame structure to unfold after ceasing applying thermal energy to the lead frame structure. In an embodiment, the lead frame structure comprises two layers with different coefficients of thermal expansion. In an embodiment, the lead frame structure is folded such that a portion of the lead frame structure is at least flush with a light emitting portion of the LED chip. In an embodiment, the lead frame structure is folded such that a portion of the lead frame structure folds down to form an electrical connection with one or more electrodes. In an embodiment, the forming of the relief lines comprises one or more of laser etching, chemical etching, or mechanical etching. In one embodiment, the lead frame structure folds via plastic deformation, while in another embodiment the lead frame structure folds via elastic deformation.

In another aspect, a lighting device includes a board; and a LED package mounted on the board, the LED package comprising a housing, a lead frame structure within the housing, the lead frame structure comprising relief lines that in response to a force being applied to the lead frame structure, cause the lead frame structure to fold along the relief lines, and an LED chip positioned on the lead frame structure.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a light-emitting diode (LED) package with a self-folding lead frame structure prior to folding according to principles of the present disclosure.

FIG. 2 is a cross-sectional view of the LED package from FIG. 1 with a self-folding lead frame structure after folding according to principles of the present disclosure.

FIG. 3 is a cross-sectional view of another LED package with a self-folding lead frame structure with different relief lines than the embodiment in FIGS. 1 and 2 prior to folding according to principles of the present disclosure.

FIG. 4 is a cross-sectional view of another LED package with a self-folding lead frame structure from FIG. 3 after folding according to principles of the present disclosure.

FIG. 5 is a cross-sectional view of lead frame structure that uses thermal energy to self-fold prior to folding according to principles of the present disclosure.

FIG. 6 is a cross-sectional view of lead frame structure that uses thermal energy to self-fold after folding according to principles of the present disclosure.

FIG. 7 is a top-down view of a lead frame structure with relief lines according to principles of the present disclosure.

FIG. 8 is a cross-sectional view of an LED package with a self-folding lead frame structure that folds in a first configuration according to principles of the present disclosure.

FIG. 9 is a cross-sectional view of an LED package with a self-folding lead frame structure that folds in a second configuration according to principles of the present disclosure.

FIG. 10 is a flow chart of a method for fabricating an LED package with a self-folding lead frame structure according to principles of the present disclosure.

FIG. 11 is a schematic diagram of a portion of an LED device, such as a display screen including a large number of LED packages according to principles of the present disclosure

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

Submounts and lead frames are two common ways to attach and make light-emitting diode (LED) components, and traditionally, this has involved attaching the LED chip to a flat submount, or on a flat lead frame structure in a housing that has minimal deformation. The range of possible form factors and product designs was therefore limited to the flat surfaces on which the LED chips were placed.

The present disclosure relates to light-emitting diode (LED) devices and more particularly to self-folding lead frames in LED packages. Exemplary lead frame structures are provided that include relief lines formed in the lead frame structure that, in response to a force being applied to the lead frame structure, for example, when an LED chip is placed on the lead frame structure, cause the lead frame to self-fold into a predefined shape. The self-folding lead frame can provide the LED package with better manipulation of light control from the package itself than conventional lead frames, while simplifying the manufacturing process. This flexibility also enables designers to create novel form factors and unconventional product designs.

Before delving into specific details of various aspects of the present disclosure, an overview of elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements.

The active LED structure can be fabricated from different material systems, with some material systems being Group III nitride-based material systems. Group III nitrides refer to semiconductor compounds formed between nitrogen (N) and elements in Group III of the periodic table, usually aluminum (Al), gallium (Ga), and/or indium (In) in the form of binary, ternary, and/or quaternary compounds. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SIC), silicon, aluminum nitride (AIN), and GaN.

Different embodiments of the active LED structure can emit different wavelengths of light depending on the composition of the active layer. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Aspects of the present disclosure are applicable to single-chip LED packages and multiple-chip LED packages where multiple LED chips are arranged within a common recess and sometimes beneath a common lens of an LED package. For multiple-chip examples, LED packages may include a red-emitting LED chip, a green-emitting LED chip, and a blue-emitting LED chip such that the LED package may be positioned as a pixel in an LED display. In other embodiments, aspects of the present disclosure may be applicable to other LED packages, such as those that include one or more LED chips with a recipient lumiphoric material that converts at least a portion of light generated from the one or more LED chips to a different wavelength.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphoric material receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a support structure of an LED package such that the anode and cathode connections are on a face of the LED chip that is opposite the support structure. In this configuration, wire bonds may be used to provide electrical connections with the anode and cathode connections. In other embodiments, a lateral geometry LED chip may be flip-chip mounted on a surface of a support structure of an LED package such that the anode and cathode connections are on a face of the active LED structure that is adjacent to the support structure. In this configuration, electrical traces or portions of a lead frame may be provided with the support structure for providing electrical connections to the anode and cathode connections of the LED chip. In a flip-chip configuration, the active LED structure is configured between the substrate of the LED chip and the support structure for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a lead frame structure. Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. Encapsulant materials may also form lenses that direct light in desired emission directions and/or patterns. In certain embodiments, one or more lumiphoric materials, such as phosphor particles, may be integrated or otherwise embedded within the encapsulant material.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

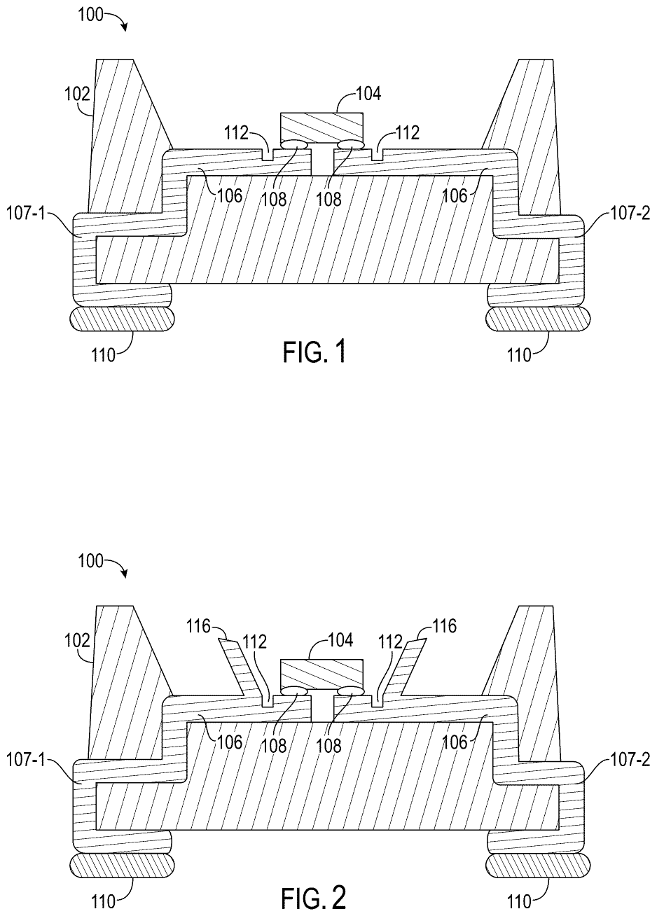

FIG. 1 is a cross-sectional view of a light-emitting diode (LED) package with a self-folding lead frame structure prior to folding according to principles of the present disclosure.

FIG. 1 includes an LED package 100 that includes a housing 102 with a lead frame structure 106 mounted therein. The lead frame structure 106 can have an LED chip 104 mounted thereon with electrodes 108 that are soldered and electrically coupled to the lead frame structure 106. The lead frame structure includes leads 107-1 and 107-2 that extend through the housing to contact the electrodes 110 (e.g., traces on a printed circuit board). In an embodiment, after the LED package 100 is fabricated, the LED package 100 may be subsequently bonded to another surface, such as within an LED display or other lighting device. In this manner, portions of the leads 107-1 and 107-2 that extend along and outside a bottom of the housing 102 are bonded with additional bonding materials.

The leads 107-1 and 107-2 of the lead frame structure 106 can include relief lines 112 that are formed in the lead. These relief lines can be mechanically formed via punchouts, or via etching, where the etching could include chemical etching (reactive ion etching, inductively coupled plasma etching), laser etching, sandblasting, or CO₂ blasting. These relief lines 112 can be formed deep enough so that the lead frame structure 106 folds across the relief lines 112 when a force is applied to one of the leads 107-1 and 107-2 due to the thinner material of the lead frame structure 106 making it more likely for the lead frame structure 106 to deform along the relief lines 112.

In an example, the relief lines 112 can be formed to remove between 20%-80% of the thickness of the leads 107-1 and 107-2 so that the lead frame structure 106 folds when a force is applied.

FIG. 2 is a cross-sectional view of the LED package from FIG. 1 with a self-folding lead frame structure after folding according to principles of the present disclosure.

After a force is applied to one or more portions of the lead frame structure 106, the folded lead portions 116 are folded into predetermined configurations, based on the application of force as well as the configuration of the relief lines 112. Here, in the example shown in FIG. 2, the folded lead portions 116, which form part of the lead frame structure 106, and previously were flattened and co-planar with the rest of the lead frame structure 106, fold upwards, thus forming sidewalls around the LED chip 104 in order to improve light extraction and/or modify the far field emission pattern of light emitted by the LED chip 104.

The force applied to the lead frame structure 106 can be applied by the die attach arm when the LED chip 104 is placed on the lead frame structure 106. In other embodiments, the folded lead portions 116 can have a similar configuration as bimetallic strip, where two layers of metals with different coefficients of thermal expansion are arranged such that in response to a change in temperature, the lead frame structure 106 and the folded lead portions 116 fold into the predefined pattern along the relief lines 112. In an embodiment, the lead frame structure 106 folds via plastic deformation, such that after the force has been removed, whether from the die attach arm or from the thermal energy being removed, the lead frame structure 106 and folded lead portions 116 stay folded.

In other embodiments, the lead frame structure 106 folds elastically or via elastic deformation, such that after the force has been removed whether from the die attach arm or from the thermal energy being removed, the lead frame structure 106 and folded lead portions 116 unfold, and return to being co-planar with each other. In an exemplary elastic deformation embodiment, application of thermal energy can cause the lead frame structure 106 to self-fold, causing the folded lead portions 116 to rise and improve light extraction or modify the light far field emission pattern. Then, when the application of thermal energy is ceased, the lead frame structure 106 unfolds, with the folded lead portions 116 returning to being co-planar with a remainder of the lead frame structure 106. The thermal energy that is applied can come from a dedicated heating element, or the thermal energy can be a by-product of the LED chip 104 can be used to control the folding of the lead frame structure 106.

It is to be appreciated that while FIG. 1 and FIG. 2 show a single LED chip mounted on the lead frame structure, in other embodiments, multiple LED chips, of the same or different colors, can be mounted on the lead frame structure, with the lead frame structure 106 providing a three-dimensional shape around a plurality of LED chips.

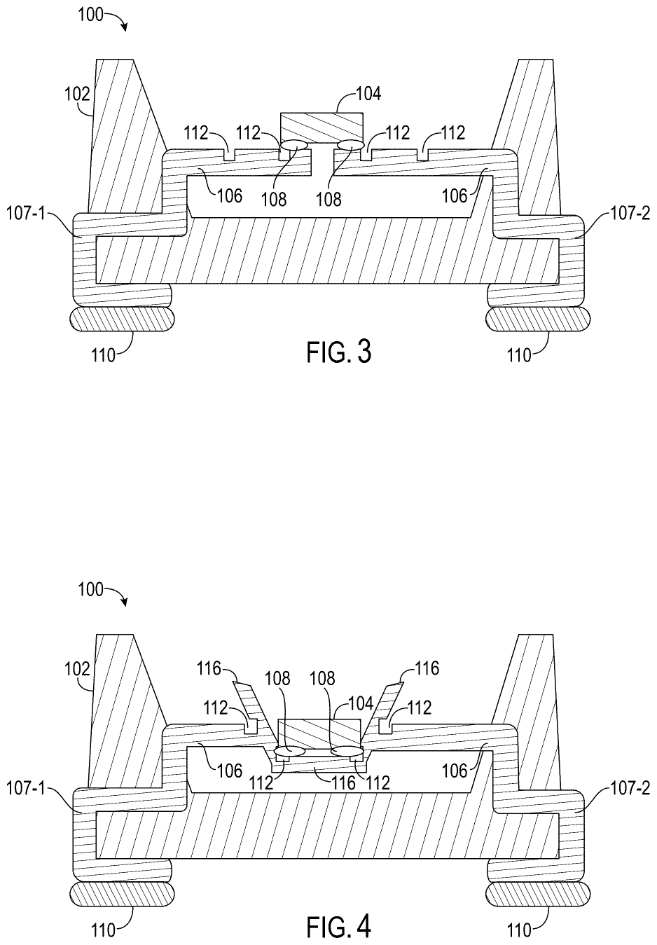

FIG. 3 is a cross-sectional view of another LED package with a self-folding lead frame structure with different relief lines than the embodiment in FIGS. 1 and 2 prior to folding according to principles of the present disclosure.

In FIG. 3, the LED package 100 includes additional relief lines 112 that can cause the lead frame structure 106 to fold differently than the embodiment in FIG. 2. In the embodiment in FIG. 3, before the lead frame structure 106 self-folds, the configuration is similar to that in FIG. 1, with LED chip 104 being mounted on a planar surface of the top of the lead frame structure. After force is applied to the lead frame structure in FIG. 4, either from application of the die attach arm attaching the LED chip 104, or from thermal energy, the lead frame structure can fold in a different configuration than the embodiment shown in FIG. 2. For example, in FIG. 4, the folded lead portions 116 can fold such that the LED chip 104 sinks below the plane on which the LED chip 104 sat before the folding of the lead frame structure 106. This type of fold can cause the relative height of the side walls formed by the folded lead portions 116 above the LED chip 104 to increase, thus further narrowing the far field emission pattern of light from the LED chip 104.

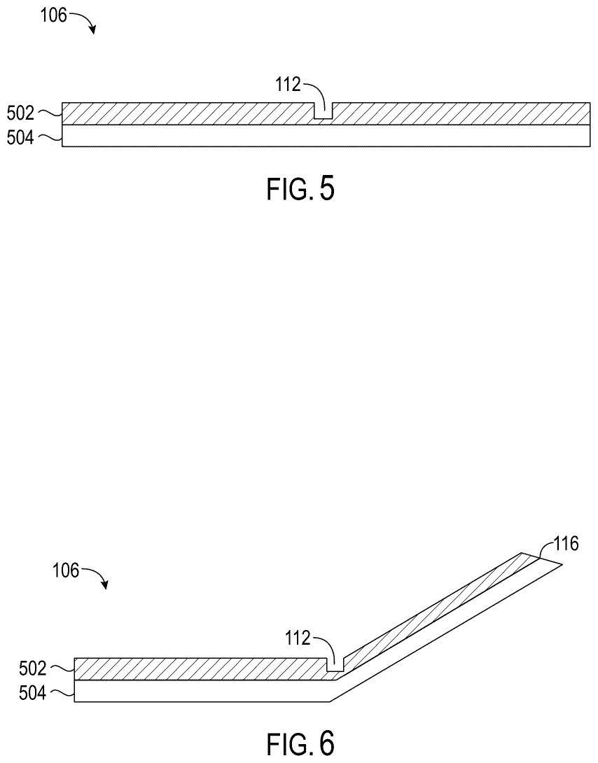

FIG. 5 is a cross-sectional view of lead frame structure that uses thermal energy to self-fold prior to folding according to principles of the present disclosure. The lead frame structure 106 in FIG. 5 can include two layers of different materials, a first layer 502 and a second layer 504. In an embodiment, these layers can be metal or be other materials as long as the coefficients of thermal expansion are different. The relief line 112 can be formed in the first layer 502, and after a change in temperature (e.g., by the application of thermal energy), in FIG. 6, the folded lead portion 116 can fold along the relief line 112 relative to a remainder of the lead frame structure 106. In the embodiment in FIGS. 5 and 6, for example, the second layer 504 can have a higher coefficient of thermal expansion than the first layer 502, thus, when thermal energy is applied, the second layer 504 expands more the first layer 502, causing the folded lead portion 116 to bend. If there were no relief line 112 present, rather than folding along a line, the folded leaf portion 116 would gradually curve. Due to the relief line 112 however, the radius of the curvature is greatly reduced.

It is to be appreciated that in the embodiments shown in FIGS. 5 and 6, the relief lines 112 are on the top surface of the lead frame structure. In other embodiments, the relief lines 112 can be formed on a bottom of the lead frame structure. Additionally, depending on the configuration of the layers with the different coefficients of thermal expansion, the folding can occur around the relief line 112 or away from the relief line 112. For example, if the first layer 502 had a larger coefficient of thermal expansion than second layer 504, the folded leaf portion 116 would bend downwards, instead of upwards as depicted in FIG. 6.

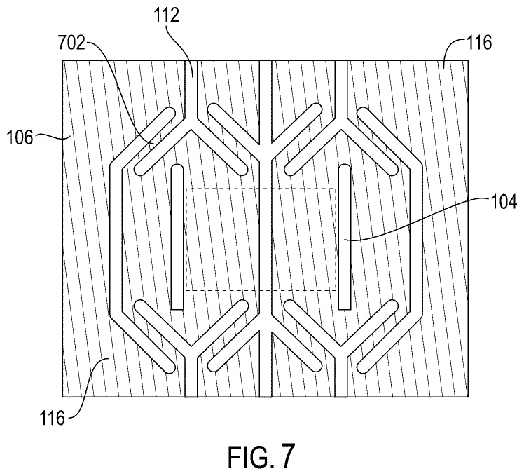

FIG. 7 is a top-down view of a lead frame structure with relief lines according to principles of the present disclosure.

The embodiment depicted in FIG. 7 shows how the relief lines 112 can form a pattern such that the folded lead portions 116 form a three-dimensional cup shape around where the LED chip 104 would be placed in the lead frame structure 106. The shape of the three-dimensional cup shape is determined based on the pattern of the relief lines 112, and the angle of the fold can be controlled based on the amount of force applied, the amount of thermal energy applied, and/or a depth and width of the relief lines 112 that are formed in to the lead frame structure 106. In an embodiment, the relief lines 112 can be formed completely through the lead frame structure and organized such that a strip of material 702 lies between relief lines 112, and the folding occurs around the strip of material 702.

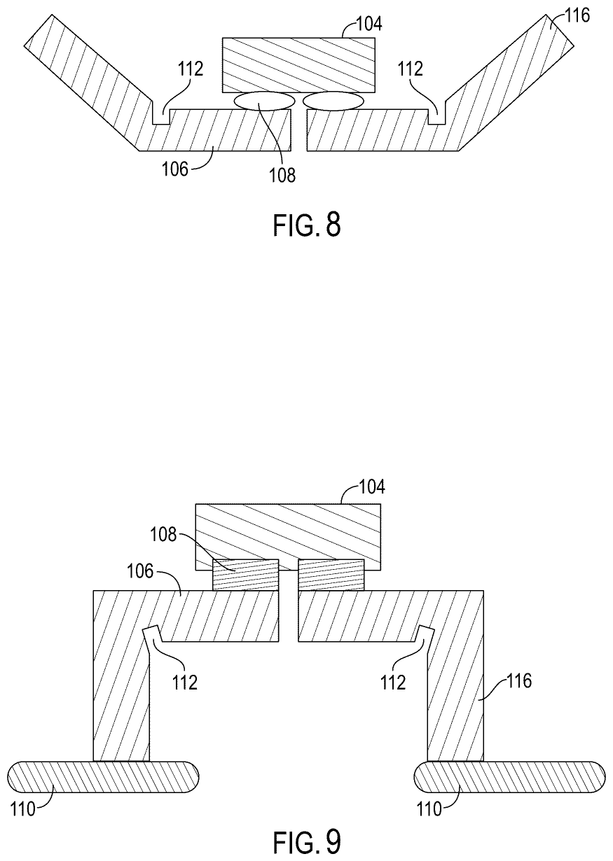

FIGS. 8 and 9 are cross-sectional views of an LED package with a self-folding lead frame structure that fold in a first and second configuration according to principles of the present disclosure.

For example, in FIG. 8, the folded leaf portions 116 can bend upwards in order to modify the far field emission pattern of the LED chip 104 and/or improve light extraction and or contrast with other LED chips that might be nearby. In other embodiments, such as in FIG. 9, the folded leaf portions 116 can bend downwards in order to make connections with electrodes 110 in the housing or submount. The folded leaf portions 116 can act, when bent downwards in FIG. 9, as socket plugs to make an electrical connection with the electrodes 110.

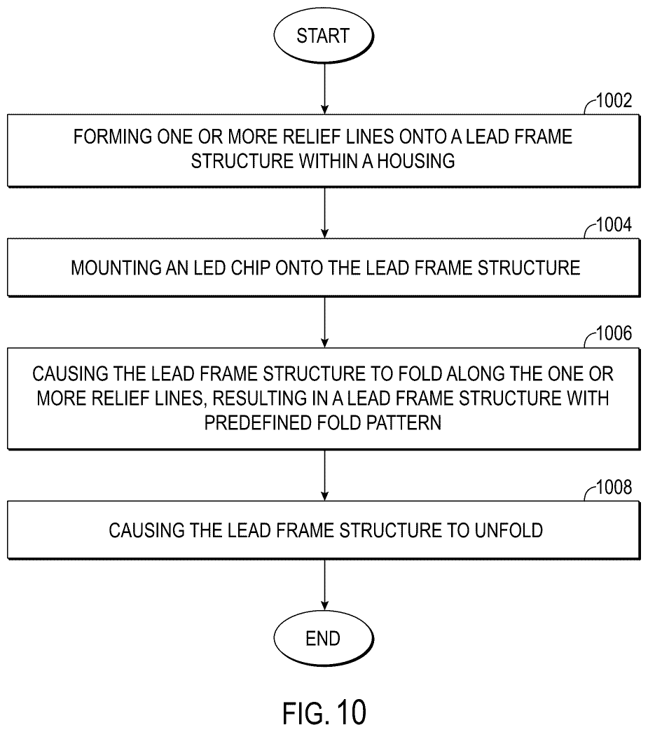

FIG. 10 is a flow chart of a method for fabricating an LED package with a self-folding lead frame structure according to principles of the present disclosure.

In an embodiment, the method can begin at 1002, where the method includes etching one or more relief lines onto a lead frame structure within a housing. The etching could include chemical etching (reactive ion etching, inductively coupled plasma etching), laser etching, sandblasting, or CO2 blasting. The etching could be performed for a predetermined length of time or intensity until the depth of the relief lines are such that the lead frame structure will fold along the relief lines reliably while not overly compromising the structural integrity of the lead frame structure.

At 1004, the method includes mounting an LED chip onto the lead frame structure. The LED chip can be a flip-chip geometry chip with electrodes 112 on the bottom of the LED chip that are placed on the leads 107-1 and 107-2 of the lead frame structure 106. The LED chip can be soldered or otherwise electrically coupled to the leads. A die attach arm can place the LED chip on the lead frame structure.

At 1006, the method includes causing the lead frame structure to fold along the one or more relief lines, resulting in a lead frame structure with predefined fold pattern. The die attach arm that places the LED chip on the lead frame structure can apply the force that causes the lead frame structure to fold. In other embodiments, thermal energy can be applied, causing the bimetallic layers with different coefficients of thermal expansion to fold across the relief lines.

At 1008, the method may optionally include causing the lead frame structure to unfold. This can occur in embodiments where the lead frame structure folds elastically, and the force that caused the lead frame structure to fold is removed. For example, in the case of thermal energy causing the lead frame portions to fold due to a differential in the coefficient of thermal expansion between metallic layers in the lead frame structure, once the thermal energy is removed, either from an external heat source, or a heat source within the LED packaging, or when the LED chip is deactivated, the lead frame structure can unfold, going back to a co-planar configuration.

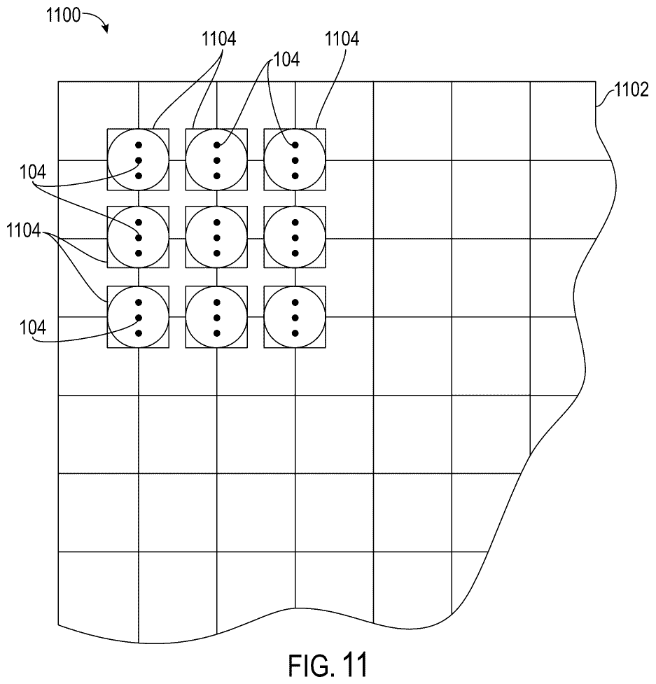

FIG. 11 is a schematic diagram of a portion of an LED device 1100, such as a display screen, for example, an indoor and/or outdoor screen comprising, in general terms, a display panel including a driver printed circuit board (PCB) 1102 carrying a large number of surface-mount devices (SMDs) 1104 arranged in rows and columns, each SMD 1104 defining a pixel. Additionally, each SMD 1104 may represent a multiple chip embodiment of different colors, such as red-green-blue, for forming an LED pixel. The SMDs 1104 are electrically connected to traces or pads on the PCB 1102 to respond to appropriate electrical signal processing and driver circuitry (not shown). While FIG. 11 depicts the LED chips 104 in a linear arrangement within each LED package for the SMDs 1104, in other embodiments, the LED chips 104 may be arranged in different configurations. During formation of the LED device 1100, the lead frame structure 106 described above can self-fold into three dimensional forms as described above. In this regard, light extraction can be improved and far field emission patterns can be modified.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light emitting diode (LED) package, comprising
a housing;
a lead frame structure within the housing, the lead frame structure comprising relief lines that in response to a force being applied to the lead frame structure, cause the lead frame structure to fold along the relief lines; and
an LED chip positioned on the lead frame structure.

2. The LED package of claim 1, wherein the lead frame structure is folded such that a portion of the lead frame structure is at least flush with a light emitting portion of the LED chip.

3. The LED package of claim 1, wherein the lead frame structure is folded such that a portion of the lead frame structure folds down to form an electrical connection with one or more electrodes.

4. The LED package of claim 1, wherein the lead frame structure comprises two layers with different coefficients of thermal expansion.

5. The LED package of claim 4, wherein the lead frame structure folds in response to a change in temperature.

6. The LED package of claim 1, wherein the relief lines are formed via etching from one or more of laser etching, chemical etching, or mechanical etching.

7. The LED package of claim 1, wherein the lead frame structure folds via plastic deformation.

8. The LED package of claim 1, wherein the lead frame structure folds via elastic deformation.

9. The LED package of claim 1, wherein the lead frame structure is folded in response to force from a die attach arm placing the LED chip on the lead frame structure.

10. The LED package of claim 1, wherein the relief lines are patterned based on a predefined fold pattern.

11. A method for fabricating a light emitting diode (LED) package, comprising:
forming one or more relief lines onto a lead frame structure within a housing;
mounting an LED chip onto the lead frame structure; and
causing the lead frame structure to fold along the one or more relief lines, resulting in a lead frame structure with predefined fold pattern.

12. The method of claim 11, wherein the causing the lead frame structure to fold comprises applying force with a die attach arm that mounts the LED chip onto the lead frame structure.

13. The method of claim 11, wherein the causing the lead frame structure to fold comprises applying thermal energy to the lead frame structure.

14. The method of claim 13, further comprising causing the lead frame structure to unfold after ceasing applying thermal energy to the lead frame structure.

15. The method of claim 13, wherein the lead frame structure comprises two layers with different coefficients of thermal expansion.

16. The method of claim 11, wherein the lead frame structure is folded such that a portion of the lead frame structure is at least flush with a light emitting portion of the LED chip.

17. The method of claim 11, wherein the lead frame structure is folded such that a portion of the lead frame structure folds down to form an electrical connection with one or more electrodes.

18. The method of claim 11, wherein the etching comprises one or more of laser etching, chemical etching, or mechanical etching.

19. The method of claim 11, wherein the lead frame structure folds via one of plastic deformation or elastic deformation.

20. A lighting device comprising:
a board; and
a light-emitting diode (LED) package mounted on the board, the LED package comprising:
a housing;
a lead frame structure within the housing, the lead frame structure comprising relief lines that in response to a force being applied to the lead frame structure, cause the lead frame structure to fold along the relief lines; and
an LED chip positioned on the lead frame structure.
